(19) United States
(12) Patent Application Publication
(10) Pub. No.: US 2025/0129543 A1
(43) Pub. Date: Apr. 24, 2025

(54) METHOD FOR GROWING ZINC-CATECHOLATE FRAMEWORKS ON BIO-FIBERS AND THEIR ELECTRONIC APPLICATIONS

(71) Applicant: QINGDAO UNIVERSITY, Qingdao, Shandong (CN)

(72) Inventors: Kewei ZHANG, Qingdao, Shandong (CN); Kai LIU, Qingdao, Shandong (CN); Yanzhi XIA, Qingdao, Shandong (CN); Xiankai LI, Qingdao, Shandong (CN); Zhe CHEN, Qingdao, Shandong (CN); Hui BIN, Qingdao, Shandong (CN)

(21) Appl. No.: 18/690,002

(22) PCT Filed: Sep. 8, 2022
(86) PCT No.: PCT/IB2022/058467

§ 371 Date: Mar. 7, 2024

(30) Foreign Application Priority Data
Sep. 8, 2021 (CN) 202111050075.7

(51) Int. Cl. D06M 11/44; C30B 7/00; C30B 7/10; C30B 29/16; C30B 29/66; D06M 101/16; G01N 21/77

(52) U.S. Cl. CPC D06M 11/44; C30B 7/005; C30B 7/10; C30B 29/16; C30B 29/66; G01N 21/77; D06M 2101/16; G01N 2021/7756

(57) ABSTRACT

The present invention provides a facile heteroepitaxial method for growing conductive zinc-catecholate frameworks on bio-fibers with biomimetic connections, which is beneficial to fabricate biocompatible and high-performance photodetectors and chemiresistors, and the corresponding bio-fiber based metal-organic framework. In this method, a conductive layer is first introduced on the surface of polysaccharide bio-fibers, before well-aligned zinc oxide nanoarrays were densely constructed on the bio-fibers by a physiological coagulation mechanism. The obtained fibrous materials may be used in devices, including in electronic components, having the advantages of good stability, environmental-friendly, flame retardancy, and high response.

### SUMMARY

This invention relates to a facile heteroepitaxial method for growing conductive zinc-catecholate frameworks on bio-fibers with biomimetic connections, which is beneficial to fabricate biocompatible and high-performance photodetectors and chemiresistors. In this method, a conductive layer was first introduced on the surface of polysaccharide bio-fibers, and then well-aligned zinc oxide nanoarrays was densely constructed on the bio-fibers by physiological coagulation mechanism. Employing fractional surface of zinc oxide nanoarrays as sacrifice, zinc-catecholate frameworks with hierarchical structure were prepared by low-temperature hydrothermal method. Benefiting from amplification effect of in-situ formed heterojunctions, promoted interfacial charge transfer is achieved, which enables the prepared material with stimuli-responsive properties, such as photoelectric and gas sensing. The obtained fibrous electronics have the advantages of good stability, environmental-friendly, flame retardancy, and high response.

### BACKGROUND

Metal-organic frameworks (MOFs) are crystalline microporous materials in which metal ions or clusters are coordinated with organic linkers to form long-range ordered crystal structures. Owing to their structural and chemical tunability, the MOFs have been widely used in adsorption, energy storage, gas separation, catalysis. However, most MOFs are inherently insulated due to low-energy barriers for charge transfer, restricting their further application in electronics, such as sensors. With the emergence of new design and synthesis strategies, the preparation of electrically conductive MOFs has become current research hotspots. Conductive 2D MOFs based on through-space or through-bond mechanisms have emerged, the most prominent of which is M₃(C₁₈H₆X₆)₂, where M=Cu, Ni or Fe; X=O or NH (C₁₈H₆O₆=2,3,6,7,10,11-hexahydroxytriphenylene (HHTP); C₁₈H₆NH₆=2,3,6,7,10,11-hexaiminotriphenylene (HITP)). These metal-catecholate frameworks with graphene-like honeycomb structure are atomically thin organic 2D materials with in-plane x-x conjugation.

Traditional growth of MOFs is based on solution reactions via the coordination between soluble metal salts and organic ligands. The resulting MOFs in the form of powders can drop-casted or spin-coated onto substrates for electronic applications, while the non-uniformity of MOFs and their significant mismatch with substrates inevitably affects the reliability of electronics. Therefore, in recent years, obtaining MOFs films on different material substrates has become a mainstream trend in MOFs synthesis and applications. Wang et al. (CN107602474A) reported a method for preparing metal-organic skeleton films (ZIF-8, ZIF-67) with specific orientation by a template method, in which metal oxide were electrodeposited on the surface of rigid substrates such as titanium sheets, conductive glass, stainless steel mesh, etc., and metal nitrates and organic ligands were used as resources. Liu et al. (CN110806430B) reported a method for in-situ synthesis of MOF films on permeable films of gas sensors, which improved sensor selectivity by the filtration of obtained MOF films. Gu et al. (CN114369252A) reported a method for preparing MOF films based on self-sacrificing crystallize metal oxide templates, but high temperature annealing treatment were required. Up to now, the development of organized 2D conductive MOFs is still limited by the use of completely rigid substrates such as silicon wafers, conductive glass, etc., thereby limiting their flexible or wearable applications. As well known, soft electronics will become a mainstream trend in the future. Mirica et al. (US20210230191A1) reported a method for oxidation of zero-oxidation state metal atoms on cotton to metallic ions, and then reaction with ligands to form MOFs. However, the current method using zero-oxidation metal sources may lead fast growth kinetics, resulting in nonuniform films on substrates and relatively poor stability of flexible electronics.

Compared with substrates such as titanium sheet, ITO glass, stainless steel mesh and traditional synthetic polymers (e.g., polyester, polyamide, polyurethane, and Kevlar), bio-fibers substrates based on polysaccharides are environmentally friendly, biodegradable and recyclable, which is important for achieving energy saving and low carbon development. To date, the growth of conductive MOFs on biofiber is crucial and highly desirable but remains a prodigious challenge, especially for fiberous soft electronics. For example, alginate fiber (AF) is a kind of polysaccharide fiber prepared by dissolving seaweed-derived sodium alginate in water through wet spinning technology, possessing excellent characteristics such as flame retardant, antibacterial, bacteriostasis, etc. Owing to easy availability of raw materials, low cost and environmental-friendly characteristics, AF has become a new favorite in textile industry in recent years. However, the polysaccharide bio-fibers are easy to swell and are not resistant to high temperature, which makes the growth of functional nanomaterials on the nonplanar organisms harsh and easy to fall off. Therefore, how to achieve shape plasticity and scale preparation of conductive MOFs materials on the surface of polysaccharide bio-fibers is the key to achieve their future application. Rational interfacial design between functional nanomaterials and nonplanar organisms will revolutionize the paradigm and future direction of device durability and user experience. The conventional solution method is cumbersome and the reaction solution conditions are relatively harsh, which is not conducive to large-scale preparation of MOFs on bio-fibers, and the final prepared materials are mostly hard substrate films without flexibility, which limits the application of such materials in the field of next-generation information materials and technologies.

A facile method of biomimetic precipitation and heteroepitaxial growth is demonstrated to grow crystalline catecholate MOFs with honeycomb lattice on biocompatible bio-fibers, which is expected to form biomimetic connections and maintain durable stability. The MOFs prepared by this method are tightly bonded between the bio-fiber/metal oxide/MOFs due to chemical bonding, which facilitates the interlayer electron transfer and makes the fiber devices equipped with this material good photoelectric and gas-sensing performance.

### BRIEF DESCRIPTION OF THE DRAWINGS

FIG. 1 is an SEM image of the silver-coated alginate fiber/ZnO prepared in embodiment 1.

FIG. 2 is an SEM image of the fiber-based Zn-HHTP prepared in embodiment 1.

FIG. 3 is SEM images of the silver-coated alginate fiber/ZnO prepared in embodiment 1 with hydrothermal time of 4 h (a), 8 h (b), and 16 h (c).

FIG. 4 is SEM images and corresponding diameter distributions of the fiber-based Zn-HHTP prepared in embodiment 1. The hydrothermal time is 5 min (a, d), 10 min (b, e), 30 min (c, f), respectively.

FIG. 5 is a diagram of the growth process of the fiber-based Zn-HHTP material prepared in embodiment 1.

FIG. 6 is XRD pattern of the fiber-based Zn-HHTP prepared by embodiment 1.

FIG. 7 shows Raman pattern of the fiber-based Zn-HHTP prepared in embodiment 1.

FIG. 8 shows XPS pattern of the fiber-based Zn-HHTP prepared in embodiment 1.

FIG. 9 shows UV-Vis pattern of the fiber-based Zn-HHTP prepared in embodiment 1.

FIG. 10 shows UPS pattern of the fiber-based Zn-HHTP prepared in embodiment 1.

FIG. 11 is a low magnification and local magnification SEM image of the fabric/ZnO prepared in embodiment 2.

FIG. 12 is low magnification and local magnification SEM image of the fiber-based paper/ZnO/Zn-HHTP prepared in embodiment 2.

FIG. 13 shows the selectivity of the fibrous photodetector for UV light at 365 nm as measured by application example 1.

FIG. 14 shows the response of the fibrous photodetector to UV light at 365 nm measured by application example 1.

FIG. 15 shows the response of the fibrous photodetector to different powers of UV light as measured by application example 1.

FIG. 16 shows the gas sensitivity response of the fabric-based gas sensor to TEA at different temperatures as measured by application example 2.

FIG. 17 shows the selectivity of the fabric-based gas sensor to TEA as measured by application example 2.

FIG. 18 shows the long-term stability of the fabric-based gas sensor measured by application example 2.

### DETAILED DESCRIPTION

In this invention, the dense thin layer of ZnO was constructed on the surface of bio-fibers by a simple hydrothermal method. A series of MOFs were synthesized by a self-sacrificing metal oxide template strategy, and the type and morphology of MOFs were strictly controlled by changing the metal oxides or MOF organic ligands.

In situ synthesis of Zn-HHTP for UV detection and TEA chemoresistive sensing when the organic ligand is 2,3,6,7,10, 11-hexahydroxybenzophenanthrene (HHTP);

The specific steps are as follows:

The cleaned bio-fibers are immersed in a metal ion solution, so that the fiber surface adsorbs metal ions and is reduced in situ to form a thin conductive layer.

Wherein said bio-fibers are alginate fibers, bamboo pulp fibers, Lyocell fibers, chitin fibers, etc. and their composite fibers.

Said bio-fibers in the form of single fibers, fiber bundles, fabric, fiber aerogel, etc.

Said metal ions are Ag⁺, Cu²⁺, Ni²⁺, etc., with a mass concentration of 10 to 35%.

Said immersion time of 10 to 60 s.

Said reduction process is: placing the fiber into 0.03-0.5% dimethylamine borane (DMAB) aqueous solution until the surface of the fiber appears metallic luster.

Bio-fibers loaded with conductive thin layer were placed in seed layer precursor solution with continuous stirring and pH adjustment to deposit oxide nanocrystalline seeds; mussel-like structure oxide nanoarrays were grown in a solution of metal salts/organic amines using low temperature hydrothermal method; bio-fiber/conductive thin layer/metal oxide nanocrystalline seed composite was obtained

Wherein said seed layer precursor solution: 5 mM ethanol solution of (Zn(CH₃COO)₂.

Said method of depositing oxide nanocrystal seeds: placing the bio-fiber loaded with conductive thin layer in the seed layer precursor solution for 5˜60 s, fishing out and drying at 100° C. for 10˜20 min, repeated 2˜10 times.

Said low temperature hydrothermal method: the deposited metal oxide nanocrystalline species of biomass fibers placed in the hydrothermal solution, 80˜120° C. at the reaction of 2˜18 h, to be cooled and removed, deionized water and ethanol alternately washed 2˜3 times.

The bio-fiber/conductive thin layer/metal oxide nanocrystal species composite obtained from the step was immersed in a mixed aqueous solution containing organic ligands (HHTP or 2-methylimidazole or BTC) and N, N-dimethylformamide (DMF) to react to obtain a bio-fiber based metal-organic framework material with a hierarchical structure.

Wherein, the total mass percentage concentration of the organic ligand and DMF in said mixed aqueous solution is 0.2 to 0.5%; the mass ratio of the organic ligand and DMF is 1:12.5.

Said reaction temperature is from 50˜80° C. and said reaction time is from 5˜80 min.

Said metal oxide nanoarray acts as a sacrificial agent, both as a metal source partially involved in the composition of the MOFs, while confining the synthesis process to a specific region, resulting in a better multilevel structure.

Further, said bio-fiber based metal-organic framework compound material has a porous array structure and bendable properties.

The present invention also provides the application of the bio-fiber based metal-organic framework compound material for photoelectric sensing, and the resulting Zn-HHTP material is made into a fiber-like photodetector with the best response to 365 nm wavelength light at an applied bias voltage of 0.5 V, with a maximum response of 0.18 A. Moreover, the material has a good response to light in the wavelength range of 300˜900 nm.

The present invention also provides the gas sensing application of the said bio-fiber based metal-organic framework compound material, which is made into a flexible gas-sensitive device with good response to hazardous gases such as TEA at room temperature, with a response of about 1.65 to TEA.

The bio-fiber based metal-organic framework compound material described in the present invention can be made into a variety of forms of fibrous, paper-based and other photoelectric sensor devices, flexible gas-sensitive devices for highly sensitive detection of different wavelengths of light as well as toxic and harmful gases.

The advantages and beneficial effects of the present invention are.

The method described in the present invention is general and the process is simple and reproducible, which is suitable for large-scale preparation. The prepared materials have a variety of physical signal responses such as photoelectricity and gas sensitivity, and the fabricated flexible sensor devices have the advantages of high responsiveness, good stability, environmental protection and flame retardancy, flexibility and bendability, which realize the functionalized application of biomass fibers.

### Embodiment 1

This embodiment relates to a method of constructing a metal-organic framework compound material on the surface of bio-fibers in the following steps.
a) Put the alginate fiber into acetone solution for 10 minutes to remove surface oil and organic matter and other impurities, and then put it into deionized water and ethanol for 10 minutes to remove residual acetone and other impurities; cut the washed alginate fiber into 2 cm fiber segments, soak in 30% mass fraction silver nitrate solution for 30 s and then pull out and rinse with pure water; put the fiber into 0.3% DMAB solution in 0.3% DMAB solution until the surface of the fiber appeared silver metallic luster and then pulled out.
b) Weighed 0.0548 g Zn (CH₃COO)₂ dissolved in 50 mL ethanol to obtain ZnO seed layer solution; weighed 0.8925 g Zn (NO₃)₂ dissolved in 60 mL deionized water, 0.4206 g HMTA dissolved in 60 mL deionized water, mixed the two solutions to obtain low-temperature hydrothermal solution; soaked the cleaned alginate fiber in ZnO seed layer solution for 10 s, fished out and then dried at 100° C. for 10 min, and after repeating twice, the fibers were put into the low-temperature hydrothermal solution and reacted at 85° C. for 6 h; the alginate fiber/ZnO material was obtained.
c) Weigh 0.007 g HHTP dissolved in a mixture of 10 mL deionized water and 1 mL DMF, put the alginate fiber/ZnO material obtained from step b) into the above mixture and react at 70° C. for 10 mins to obtain the metal-organic framework material (Zn-HHTP) constructed on the surface of bio-fiber.

The obtained products were characterized as follows.

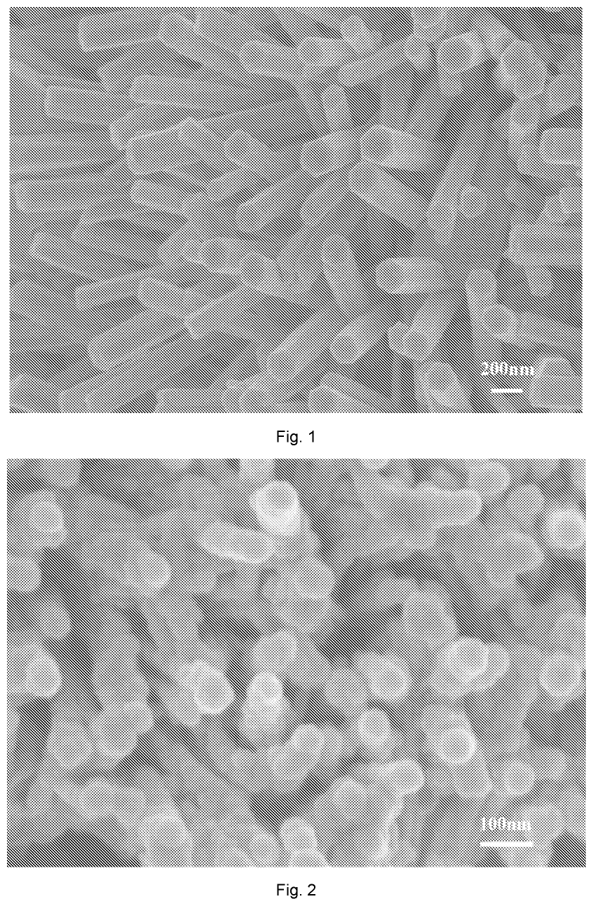

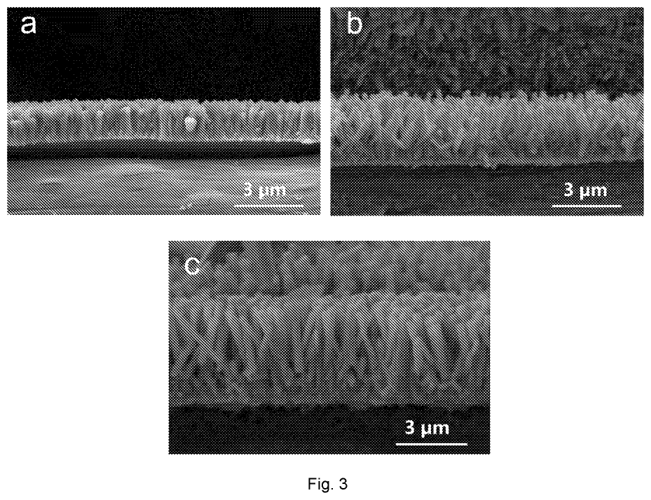

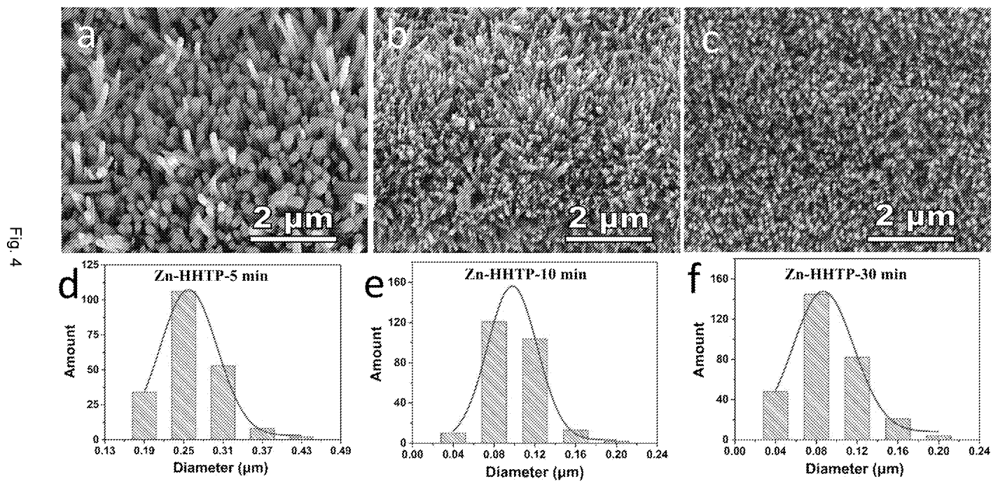

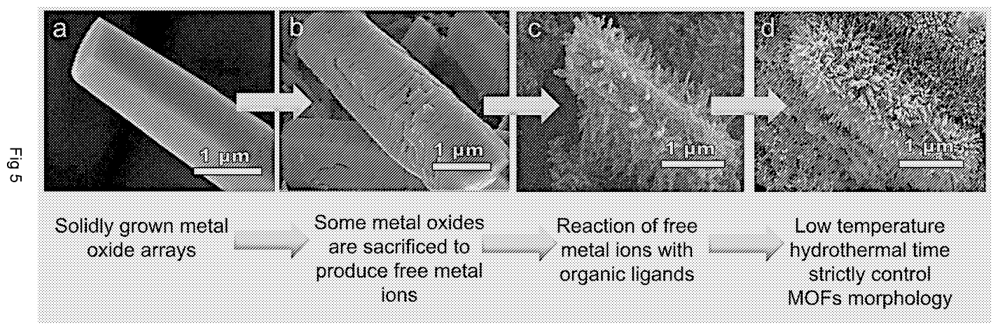

Scanning electron microscopy (SEM) was used to observe the surface morphology of alginate fiber/ZnO before and after the synthesis of Zn-HHTP, as shown in FIGS. 1 and 2. As seen from the figures, the ZnO nanorods before the reaction with HHTP were regular hexagonal arrays with diameters around 100-200 nm and smooth surfaces (FIG. 1), while the ZnO nanorods after the reaction were nanorods with diameters around 50 nm (FIG. 2). After 8, 16 and 24 hours of hydrothermal treatment, the length of ZnO nanoarray were ˜2 μm, ˜3 μm and ˜4 μm, respectively (FIG. 3). FIG. 4 is for Zn-HHTP-5 min, Zn-HHTP-10 min and Zn-HHTP-30 min samples, where 5, 10, and 30 denotes the immersion time in HHTP solution is 5 min, 10 min, and 30 min, respectively. The amount of Zn-HHTP increases with increasing low-temperature hydrothermal time. So it's clear that, the length and thickness of ZnO and Zn-HHTP can be strictly controlled by hydrothermal time. The growth process of Zn-HHTP is shown schematically in FIG. 5. The surface of ZnO becomes rough because some of the Zn²⁺ become free in the mixed solution. When the dissociative Zn²⁺ meet the metal-ligand of HHTP resulting in the formation of Zn-HHTP.

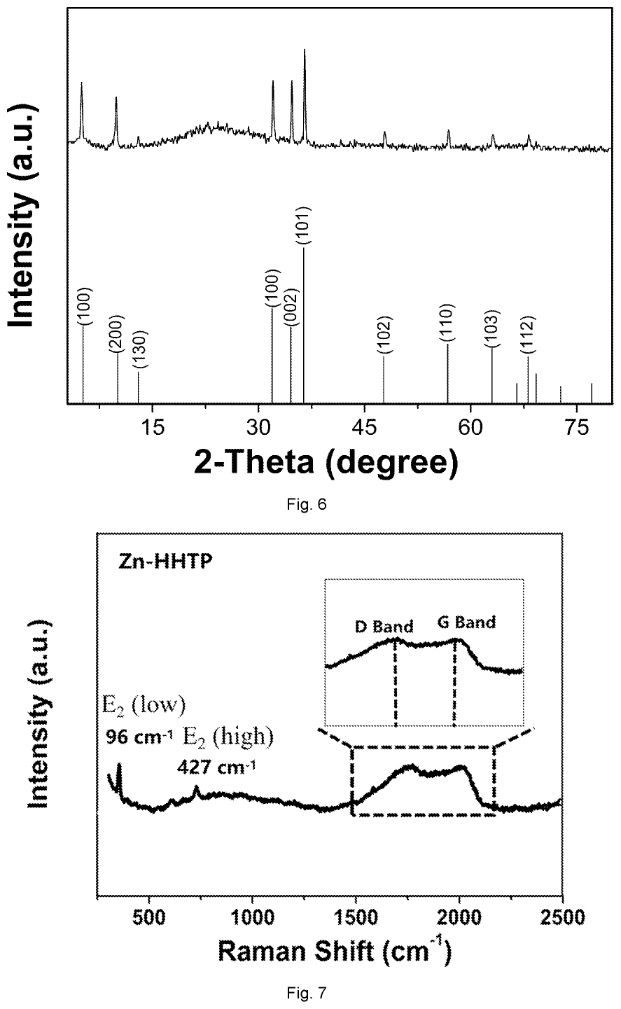

X-ray powder diffraction (XRD) was used to characterize the physical phase structure and crystalline shape of the synthesized Zn-HHTP, and the results are shown in FIG. 6, where each characteristic peak of ZnO is in general agreement with the Joint Committee on Powder Diffraction Standards PDF #36-145, and its peaks at 31.769°, 34.421°, 36.252°, 47.538°, 56.602°, 62.862°, 67.961°, etc. correspond to the (100), (002), (101), (102), (110), (103), (112) crystallographic planes of ZnO, respectively, which prove the successful preparation of ZnO; the diffraction peaks at 5.000°, 9.921°, 13.083°, etc. correspond to the (100), (200), (130) crystal plane, which is basically consistent with the simulated XRD diffraction pattern of Zn-HHTP, proving the successful preparation of Zn-HHTP.

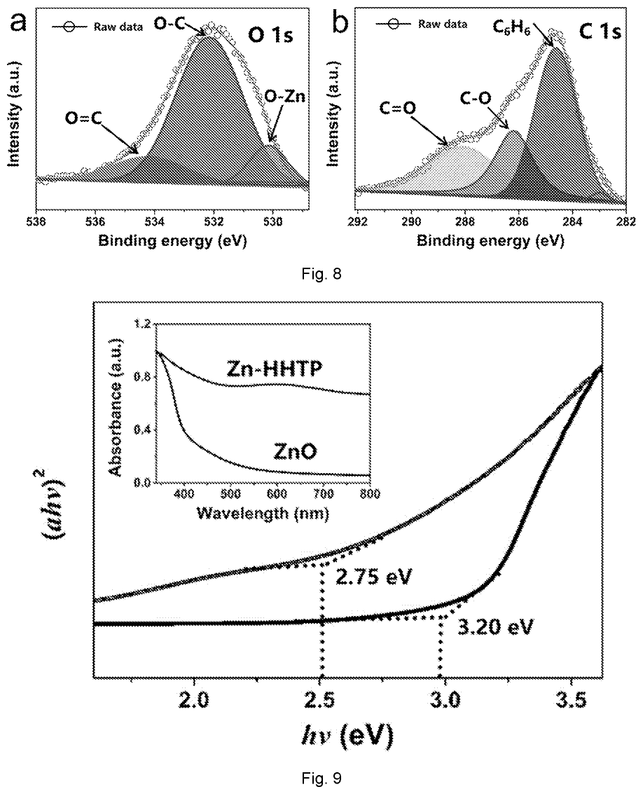

FIG. 7 illustrates the Raman pattern of fiber-based Zn-HHTP, the E₂ (low) mode at 96 cm⁻¹ and the E₂ (high) mode at 427 cm⁻¹ are both characteristic peaks of ZnO. Zn-HHTP, a catecholate frameworks, due to its graphene-like structure, makes the two “mushroom peaks” appear in the range of 1200˜1800 cm⁻¹, which is reminiscent of the D and G bands of graphene. FIG. 8 illustrates the XPS pattern of fiber-based Zn-HHTP, deconvoluted high resolution spectrum for O 1 s (FIG. 8(a)) reveals the presence of three different environments at 530.6 eV, 532 eV and 534.2 eV, which can be assigned to O−Zn, O−C, and O═C, respectively. Similarly, the C Is spectrum (FIG. 8(b)) was deconvoluted to three peaks at 284.3 eV, 286.1 eV, and 288.2 eV, corresponding to semi-quinone and quinone, C—O and C═O in the HHTP structure, respectively.

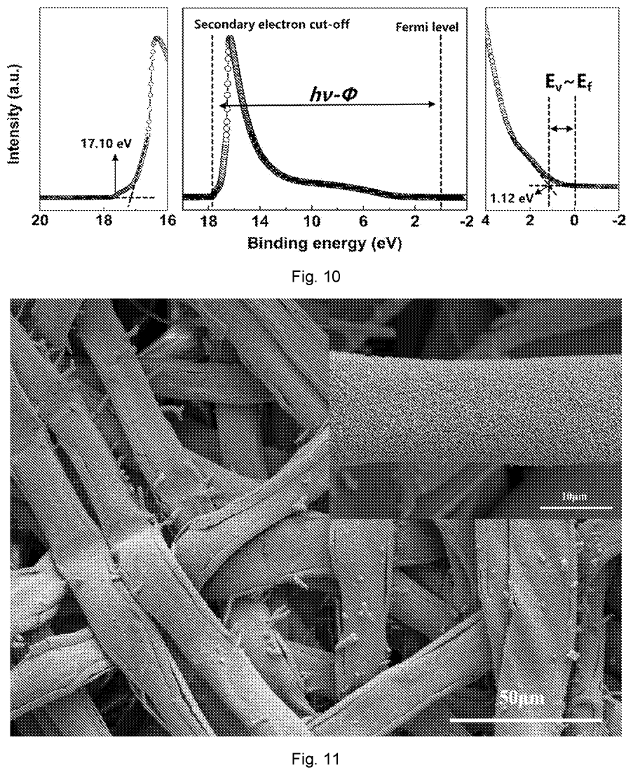

FIGS. 9 and 10 illustrates the UV-Vis and UPS pattern of fiber-based Zn-HHTP, the band gap of ZnO and Zn-HHTP were determined to be 3.2 eV and 2.75 eV, respectively. The energy state of Zn-HHTP in the visible region (2.75 eV) is related to the π-π* transition of the HHTP link.

### Embodiment 2

This embodiment relates to a method for constructing a metal-organic framework compound material on the surface of biomass fibers in the following steps.
a) Put the Lyocell fiber into acetone solution for 10 minutes to remove surface oil and organic matter and other impurities, and then put it into deionized water and ethanol for 10 minutes to remove residual acetone and other impurities; cut the washed Lyocell fiber into 1×1 cm size, soak in 30% mass fraction silver nitrate solution for 30 s and then pull out and rinse with pure water; put the fiber into 0.3% DMAB solution in 0.3% DMAB solution until the surface of the fiber appeared silver metallic luster and then pulled out.
b) Weighing 0.0548 g Zn (CH₃COO)₂ dissolved in 50 mL ethanol to obtain ZnO seed layer solution; weighing 0.8925 g Zn (NO₃)₂ dissolved in 60 mL deionized water and 0.4206 g HMTA dissolved in 60 mL deionized water, mixing the two solutions to obtain low-temperature hydrothermal solution; placing the washed Lyocell fabric was soaked in the ZnO seed layer solution for 10 min, fished out and dried at 100° C. for 10 min, and after repeating twice, the fibers were put into the low-temperature hydrothermal solution and reacted at 85° C. for 24 h; Lyocell fabric/ZnO material was obtained.
c) 0.015 g of HHTP was weighed and dissolved in a mixture of 20 mL of deionized water and 2 mL of DMF. Put the alginate fiber/ZnO material obtained from step b) into the above mixture the fibers and reacted at 60° C. for 80 min to obtain fabric-based metal organic framework material (Zn-HHTP).

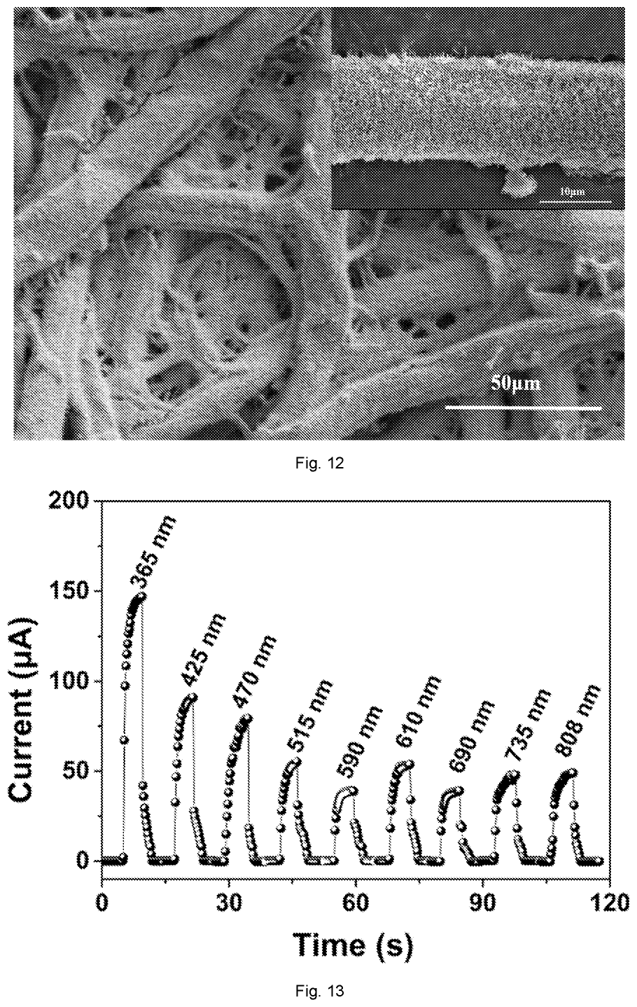

The surface morphology of the Lyocell fabric/ZnO before and after the synthesis of Zn-HHTP was observed by scanning electron microscopy (SEM) as shown in FIGS. 11 and 12. As seen from the figures, the surface of the fabric after the growth of ZnO showed a regular arrangement of ZnO arrays (FIG. 11), and the surface of the fabric after the continued generation of Zn-HHTP was disrupted due to the sacrifice of some ZnO as a template, so the regular arrangement of arrays (FIG. 12), which shows a random growth.

### Embodiment 3

a) Put the alginate fiber into acetone solution for 10 minutes to remove surface oil and organic matter and other impurities, and then put it into deionized water and ethanol for 10 minutes to remove residual acetone and other impurities; cut the washed alginate fiber into 2 cm fiber segments, soak in 30% mass fraction silver nitrate solution for 30 s and then pull out and rinse with pure water; put the fiber into 0.3% DMAB solution in 0.3% DMAB solution until the surface of the fiber appeared silver metallic luster and then pulled out.
b) Weighed 0.0498 g Cu (CH₃COO)₂ dissolved in 50 mL ethanol to obtain CuO seed layer solution; weighed 0.725 g Cu (NO₃)₂ dissolved in 60 mL deionized water, 0.4206 g HMTA dissolved in 60 mL deionized water, the two solutions mixed to obtain a low-temperature hydrothermal solution; the cleaned alginate fiber soaked in CuO seed layer solution for 10 s, fished out and then dried at 100° C. for 10 min, repeat twice and then put the fibers into the low-temperature hydrothermal solution and react at 85° C. for 6 h; obtain the alginate fiber/CuO material.
c) Weigh 0.007 g BTC dissolved in a mixture of 10 mL deionized water and 1 mL DMF, put the alginate fiber/CuO material obtained from step b) into the above mixture and react at 70° C. for 10 min to obtain the metal-organic framework material (Cu-BTC) constructed on the surface of bio-fiber.

### Application Example 1

The photodetectors made from Zn-HHTP fibers in Embodiment 1 were subjected to a single-order constant voltage output system in Keithley dual-channel source meter integrated measurement software to determine their photovoltaic performance for different wavelengths of light.

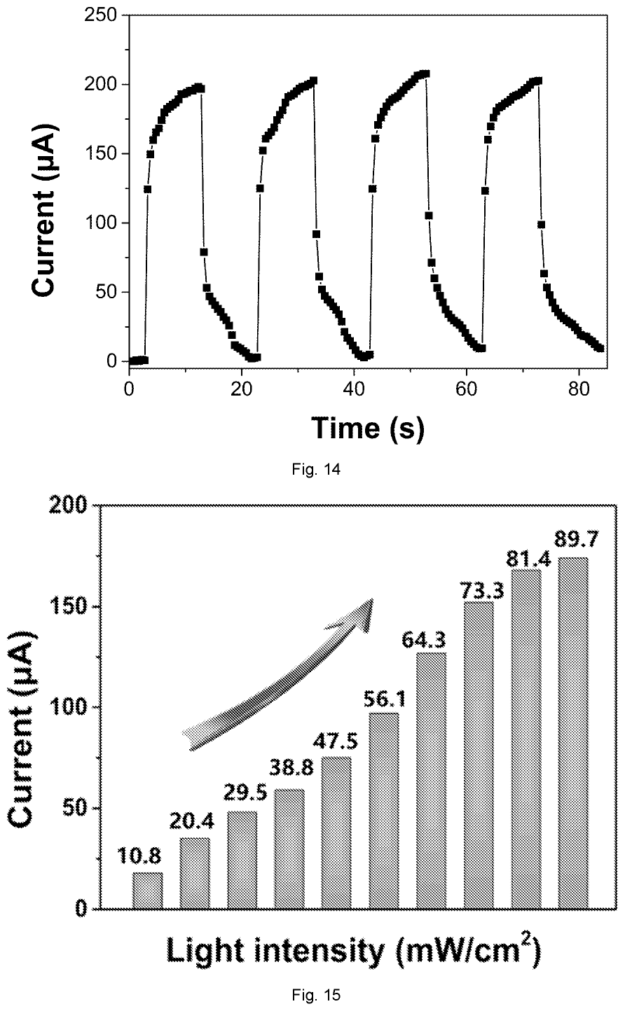

The specific application results are shown in FIGS. 13-15, which indicate that the photodetector made of this MOF material has good response in the wavelength range of 300˜900 nm under the condition of applied 0.5 V bias voltage, and the best response to 365 nm wavelength light (FIG. 13), with the highest response of 0.18 A (FIG. 14). As shown in FIG. 15, the photocurrent values of the photodetector increase significantly with increasing optical power density. This is because Zn-HHTP is a semiconductor material with high specific surface area and porosity, and ZnO is a common n-type semiconductor, and the heterogeneous structure formed by depositing the two semiconductor materials together on the seaweed fiber base can greatly increase the electron-hole complexation rate. of the solar spectrum.

### Application Example 2

The ends of the Zn-HHTP fabric made in Embodiment 2 were wrapped with double-sided copper tape to be used as electrodes; the fabric was put into the vacuum chamber of the gas-sensitive test apparatus, and the electrodes were connected and detected for TEA.

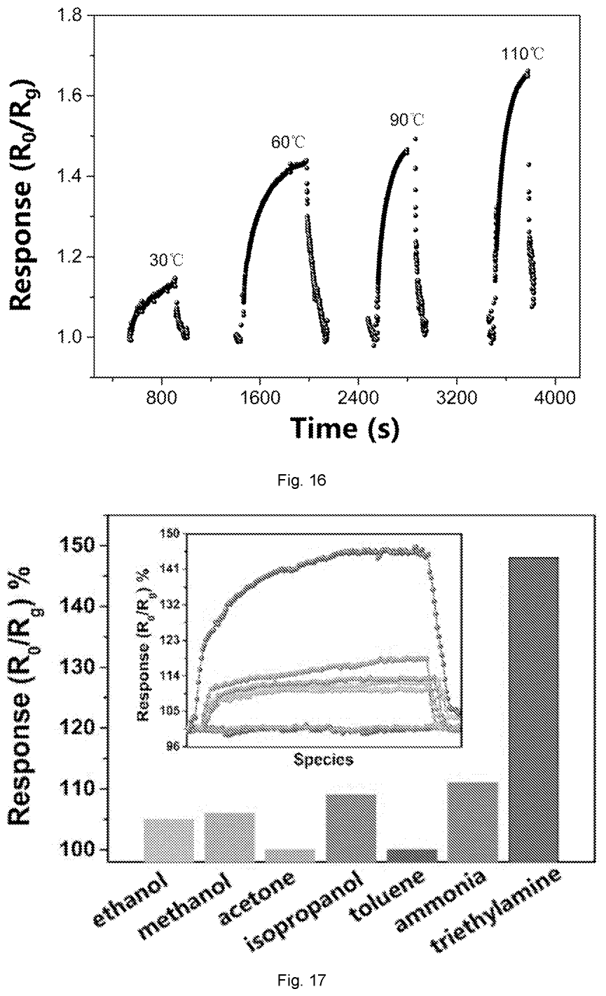

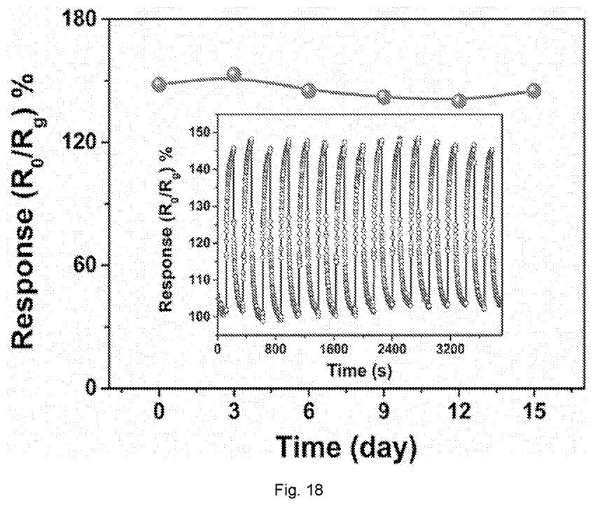

The specific application results are shown in FIG. 16-19. At room temperature, when 2 μL of TEA was injected, the device had a response of about 1.65 to TEA, and then the temperature conditions were changed to 60° C., 90° C. and 110° C., and the gas sensitivity of the device to TEA gradually increased (FIG. 16). In addition to this, the device has good immunity to interference and can accurately identify TEA (FIG. 17). It also has a good long-term stability (>2 weeks, FIG. 18). These results cannot be achieved without the high specific surface area and porosity of the material, so it can respond well to hazardous gases such as TEA at room temperature.

1. The invention effectively solves the problem that functional nanomaterials are difficult to grow on the surface-swelling bio-fibers, and the prepared bio-fiber based metal-organic framework compound material grows firmly and densely on the fiber surface layer by layer due to chemical bonding.

2. The material described in the present invention is based on bio-fibers. Unlike common substrate materials (e.g., conductive glass, silicon wafers, carbon cloth, polymer films, and other flat substrates), the surface of the fibrous substrate is curved and curved, and the surface cannot be completely covered when the material is grown by magnetron sputtering, liquid phase epitaxy, etc., but the present invention uses low temperature hydrothermal method to effectively solve this problem.

3. The method in claim 2 is carried out as follows.
a) Depositing metal oxide nanocrystalline seeds by placing the cleaned metal-coated bio-fiber substrate in a seed layer precursor solution with continuous stirring and pH adjustment; growing mussel-structured oxide nanoarrays in a solution of metal salts/organic amines using hydrothermal method; obtaining bio-fiber/metal oxide nanocrystalline seed composites.
b) The bio-fiber/oxide nanoarrays were immersed in a mixed aqueous solution containing organic ligands and DMF for the reaction to obtain constructing metal-organic framework materials on the surface of bio-fibers.

4. The method for constructing metal-organic framework material on the surface of bio-fibers according to claim 3, characterized in that said fibers are algae fibers, bamboo pulp fibers, Lyocell fibers, chitin fibers or composite fibers; said bio-fibers are in the form of single fibers, fiber bundles, fabric or fiber aerogel.

5. The method for constructing metal-organic framework materials on the surface of bio-fibers according to claim 3, characterized in that said metal-organic preparation method is universal and only requires corresponding changes in the acetic acid salt in the seed layer precursor solution and the nitrate species in the low-temperature hydrothermal solution to obtain metal oxides that can be ZnO, CuO, NiO, etc.

6. The method for constructing metal-organic framework material on the surface of bio-fibers according to claim 3, characterized in that said organic ligands are HHTP, 2-methylimidazole, BTC, etc.

7. The method of constructing metal-organic framework material on the surface of bio-fibers according to claim 3, characterized in that the preparation of seed layer precursor solution in said step a) is: 5 mM ethanol solution of metal salts (Zn(CH₃COO)₂) to obtain the metal oxide seed layer precursor solution; said method of depositing metal oxide nanocrystal seeds: the cleaned bio-fibers were placed in the seed layer precursor solution and soaked for 5 s˜10 min, fished out and dried at 100° C. for 10˜20 min, and repeated 2˜10 times.

8. The method of constructing metal-organic framework materials on the surface of bio-fibers according to claim 3, characterized in that said metal salt/organic amine solution is prepared by: 100 mM aqueous solution of nitrate (Zn(NO₃)₂, 100 mM aqueous solution of HMTA, mixing the two solutions well; said low-temperature hydrothermal method: the bio-fibers deposited with metal oxide nanocrystalline species were placed in a hydrothermal solution and reacted at 80˜120° C. for 2˜18 h. After cooling, they were removed and washed 2˜3 times with deionized water and ethanol alternately.

9. The method for constructing metal-organic framework materials on the surface of bio-fibers according to claim 3, characterized in that said step b) has a reaction temperature of 50˜80° C. and said reaction time of 5˜80 mins.

10. The method for constructing metal-organic framework materials on the surface of bio-fibers according to claim 3, characterized by having a porous array structure and bendable properties.

11. The bio-fiber based metal-organic framework compound material described in the present invention can be made into a variety of forms of fibrous and paper-based photoelectric sensor devices, flexible gas-sensitive devices for highly sensitive detection of different wavelengths of light as well as toxic and hazardous gases.

12. The bio-fiber based metal-organic framework compound material as claimed in claim 3 for application in photoelectric sensing.

13. The bio-fiber based metal-organic framework compound material as claimed in claim 3 for application in gas sensing.
